(19) United States
(12) Patent Application Publication
(10) Pub. No.: US 2009/0084310 A1
(43) Pub. Date: Apr. 2, 2009

(54) Method for manufacturing single crystal nano-structures capable of controlling morphology and device for manufacturing nano-structures

(76) Inventors: Si-Kyung Choi, Yuseong-ku (KR); Hyun-Jung Kim, Pocheon-si (KR)

Correspondence Address: THE NATH LAW GROUP, 112 South West Street, Alexandria, VA, 22314, US

(21) Appl. No.: 11/987,412

(22) Filed: Nov. 29, 2007

(30) Foreign Application Priority Data
Sep. 28, 2007 (KR) 10-2007-0098242

(51) Int. Cl. C30B 23/00; C30B 11/00

(52) U.S. Cl. 117/108; 117/200

(57) ABSTRACT

The present invention discloses a method for manufacturing single crystal nano-structures capable of controlling morphology so as to allow materials with various morphologies to form nano-structures in desired morphologies and a device for manufacturing the nano-structures, according to variables such as a temperature of a target member in a vacuum system, an applied voltage applied to the target member, a pulse width, a kind of precursors after vaporization of the target member, etc. Each of the nano-structures of the present invention can be used as a unit of a storage medium so that a high density storage medium can be manufactured and various devices can be miniaturized by using particular electrical and physical characteristics that are exhibited in a nano-size semiconductor or metal.

This application claims priority to Korean Patent Application No. 10-2007-0098242, filed on Sep. 28, 2007, in the Korean Intellectual Property Office, the entire contents of which are hereby incorporated by reference.

### BACKGROUND OF THE INVENTION

1. Field of the Invention

The present invention relates to a method for manufacturing single crystal nano-structures capable of controlling morphology so as to allow materials with various morphologies to form nano-structures in desired morphologies on a substrate whose temperature can be controlled and a device for manufacturing the nano-structures, according to variables such as a temperature of a target member in a system, an applied voltage applied to the target member, a pulse width, a kind of precursors after vaporization of the target member, etc.

2. Description of the Related Art

In a memory industry, research and development of a next-generation semiconductor memory, which is a non-volatile memory faster and smaller in size and a circuit line width than current standard DRAM or flash memory, has been actively progressed.

As a representative next-generation memory, there are a phase-change random access memory (PRAM), a ferroelectric random access memory (FRAM), and a magnetic random access memory (MRAM), etc.

A memory such as the phase-change random access memory and the ferroelectric random access memory, etc., has been spotlighted as an optimal memory in view of performance, process, speed, etc. Accordingly, in such a memory, an effort to increase the degree of integration of information storage has been continuously made.

It is expected that a lithography process using an ArF light source, which has been currently used in a semiconductor manufacturing process, will have substantially reached its limits by 2012 at which a minimum line width of a semiconductor device will reach approximately 22 nm.

Since chalcogenide materials (Ge—Sb—Te alloys) undergo reversible phase-change between a crystalline phase and an amorphous phase according to the application of heat, they have been widely used as an electrical and optical information storage medium.

Since the composition of Ge₂Sb₂Te₅(GST) among the compositions of various ternary Ge—Sb—Te has advantages of fast phase-change time (<100 ns) to a crystalline phase, high thermal stability in a normal temperature range, a completely reversible phase-change between a crystalline phase and an amorphous phase, etc., it has been widely used.

Therefore, the phase-change random access memory using the GST is a memory that can pass limits of currently used memories. However, there is a limitation in controlling sizes of GST cells to sublithographic length scales.

A reduction of the size of the GST cell is very important factor to reduce a reset current required for a phase-change from an initial crystalline phase to an amorphous phase, since this is directly linked with power consumption.

A top-down scheme by means of the lithography process has a large possibility of a damage of cell characteristics due to surface damage after the process. Also, even though heat treatment is performed after the process, the cell may exhibit a change in characteristics after the heat treatment.

Only a bottom-up scheme for manufacturing nano-structures, which overcomes the problems in manufacturing a chalcogenide thin film through a deposition of the existing top-down scheme, will be the key to reducing a device size.

Accordingly, the control and growth of the nano-structures such as nanowires, nanotubes, nanorods, etc., will greatly increase the possibility of control of a small-sized memory with the help of a sublithographic size and a unique geometry.

The growth method of the nano-structures used a chemical reaction in a reduction atmosphere in the early 1960s and many efforts to manufacture a micrometer sized crystal whisker using the evaporation and condensation of materials, in particular a metal whisker were made. Thereafter, various methods for manufacturing a nano-sized whisker have been studied.

As the methods for manufacturing the nano-sized whisker, there are a chemical vapor deposition (CVD) method, a laser ablation method, a vapor phase evaporation method, and the like.

The chemical vapor deposition method is the most effective method involving a thin film growth. The general chemical vapor deposition method is applied to the synthesis of nanowires using an impurity as a catalyst. At an initial stage, it is used for growing the metal whisker and is then applied to manufacture the whisker of Si, Ge, GaAs, InP, etc.

A material (catalyst) forming a liquid phase is used in this experiment. Nano-sized particles are observed in an end portion of a nanowire. This is important evidence of a vapor liquid solid (VLS) growth mechanism.

The laser ablation method is a method that evaporates a target member by an ion beam using an excimer laser ablation method. Also, it is used for manufacturing a thin film at an initial stage. Recently, it is used for manufacturing a single-walled carbon nanotube (CNT) or a boron nitride (BN) nanotube by combining with an evaporation method in a high temperature furnace.

The difference between the thin film growth using this method and the nano-sized material growth is as follows: the former allows the deposition to be directly made on a substrate by directly impacting laser on the target, while the latter does not have the substrate and allows removed atoms to form one-dimensional nano-structures.

Also, the vapor phase evaporation method manufactures the micro-sized whisker via a vapor phase. This attempt was widely made in the 1960s. As a result, many kinds of metal and oxide whiskers were manufactured. Such a whisker is manufactured merely by physically sublimating materials or by a reduction of volatile metal halides.

A mass synthesis of various nano-sized materials has been recently achieved by means of the vapor phase evaporation method.

Also, many methods for manufacturing the nano-structures have been studied for the past several decades. Among others, a vapor-liquid-solid (VLS) method is used as a new method for growing quantum dots, semiconductor nanowires in IV and III-V morphologies, and metal oxide nano-structures, that is, a method for growing chalcogenide-based nano-structures.

The VLS growth intentionally uses an impurity or a catalyst called a second phase in order to grow the crystals in a restricted region in a particular direction. The catalyst is made into a morphology of a liquid phase drop or is mixed with a growth material in the growth process. The growth material fully filled in the catalyst drop is condensed at a growth surface and at the same time, can be grown in one direction.

As one example, the VLS method is used in order to grow single crystal GeTe nanowires and nanohelices with phase-change characteristics (Dong Yu, et al., “Germanium Telluride Nanowires and Nanohelices with Memory-Switching Behavior,” J. Am. Chem. Soc., 128, 8148 (2006)). The GeTe(99.99% Sigma-Aldrich) in a bulk morphology is volatized at a central portion of a horizontal tube furnace and a SiO₂ substrate covered with Au nanoparticles in a colloidal morphology reacts with vaporized GeTe particles in a downstream region to the horizontal tube furnace to form the nano-structures.

As another example, The VLS method using a metal catalyst and a vapor phase material movement is used in order to grow Ge₂Sb₂Te₅ nanowires (Yeonwoong Jung et al., “Synthesis and characterization of Ge₂Sb₂Te₅ nanowires with memory switching effect,” J. Am. Chem. Soc., 128, 14026 (2006)). GeTe, Sb, and Te powder is used as a supply source of precursor. Since a melting temperature of each material is different, their positions are controlled within the tube furnace to control the degree of vaporization of each material. The nanowires are grown on the Si substrate covered with the Au catalyst in a colloidal morphology.

As another example, in order to grow the nanowires with the compositions of GeTe and Sb₂Te₃, The same VLS method as described above is used (Stefan Meister et al., “Synthesis and characterization of Phase-Change nanowires,” Nano Letters, 6, 1514 (2006)). The substrate uses a Si wafer on which a 50 nm Au colloidal aqueous solution is sprayed, the bulk precursor volatized by vaporization is positioned at the central portion of the tube furnace, and the Si wafer is positioned at a low temperature downstream of the furnace into which N₂ gas containing H₂ gas of 5% flows.

And, nano-structures growing and applying methods using chalcogenide materials are proposed in the following patents.

Korean Patent Laid-Open No. 10-2005-0005122 (Manufacturing method of ZnO nanowires and ZnO nanowires manufactured therefrom) relates to a manufacturing method of ZnO nanowires comprising the steps of particulating Zn metal and oxidizing the particulated Zn particles in the air at atmospheric pressure to form the ZnO nanowires on a surface, wherein the step of particulating Zn deposits the Zn metal on a sapphire substrate using a thermal deposition method. Also, in the step of oxidizing the Zn particles, if oxidization temperature and oxidization time are controlled, the size of ZnO nanowires on the surface can be controlled.

Korean Patent Laid-Open No. 10-2005-0077678 (Manufacturing method of silicon carbide nanorods and nanowires) provides a manufacturing method of silicon carbide nanorods and nanowires capable of manufacturing a large amount of silicon carbide nanorods and nanowires at a low temperature by coating a surface of a carbon structure using a transition metal as a metal catalyst and then reacting the coated carbon structure with a mixed powder of silicon and silicon dioxide.

Korean Patent Laid-Open No. 10-2006-0115828 (Phase-change memory device comprising nanowires and manufacturing method thereof) provides a phase-change random access memory (PRAM) comprising a lower structure including a contact plug, a nanowire formed to be extended from the surface of the contact plug to the lower portion, and a phase-change film formed on the nanowire and a manufacturing method thereof. Therefore, a reset current or a set current required in the PRAM device can be greatly reduced.

### SUMMARY OF THE INVENTION

Various studies on the methods for growing the nano-structures as described above are underway. However, these methods have several limitations.

The vapor-liquid-solid (VLS) method (Lieber et al., Science, 279, 208 (1998)) and a solution-liquid-solid method (Lieber et al., J. Am. Chem. Mater., 122, 8801 (2000)), etc., which are mainly discussed as the method for synthesizing the nano-structures by making the precursors into the vapor phase, are reported.

However, the methods are experiencing manufacturing difficulties due to the involvement of the high temperature reaction of 700 to 1000° C. Also, the size of a nanowire grown by means of the VLS method is determined by the size of liquid catalyst, wherein since the size of liquid catalyst drop has a limitation, if the size is large to a certain degree, the size of the nanowire cannot be further reduced. In other words, when intending to grow very thin nanowires, small catalyst drops are needed. However, since a convex surface having a very small diameter has large solubility, the supersaturation of vapor phase is large so that the lateral growth by way of the vapor-solid mechanism occurs. Therefore, it is difficult to form the nano-structures with a uniform size.

Also, the Laid-Open patents as described above have limitations. In the case of Korean Patent Laid-Open No. 10-2005-0005122, it has a disadvantage that the nano-structures can be formed in a desired morphology by experiencing the processes several times. Further, in the case of Korean Patent Laid-Open No. 10-2005-0077678, it has a disadvantage that a lowest temperature proposed in the patent is in real terms a very high temperature of 1100° C.

And, the methods for manufacturing the nano-structures as proposed in the articles or the patents as described above should be matched with the properties of each material in order to grow particular materials. That is, the range of materials selection is very restricted.

In order to solve the problems, it is an object of the present invention to provide a method for manufacturing single crystal nano-structures capable of controlling morphology so as to allow materials with various morphologies to form nano-structures in desired morphologies on a substrate whose temperature can be controlled, according to variables such as a temperature of a target member in a vacuum system, an applied voltage applied to the target member, a pulse width, a kind of precursors after vaporization of the target member, etc.

It is another object of the present invention to provide a device for manufacturing nano-structures with a simple structure comprising a target member performing a function of supplying precursors, a substrate on which nano-structures will be formed, and a part of a piezo-motion (PZT scanner) or a Z-motion unit for controlling a distance between two thin films so as to allow manufacture of nano-structures wherein it is possible to control morphology according to variables such as a temperature of a substrate in a vacuum system, an applied voltage applied to a target member, a pulse width of the applied voltage, etc.

In order to accomplish the objects, there is provided a method for manufacturing single crystal nano-structures capable of controlling morphology according to the present invention comprises the steps of: disposing a target member supplying precursors inside a space with a vacuum atmosphere; disposing a substrate to be formed with the nano-structures above or below the target member; controlling a distance between the target member and the substrate; heating the target member at a constant temperature according to the desired morphology of the nano-structures; and vaporizing the target member by applying a pulse voltage to the target member.

Herein, the heating temperature is below the melting point of the target member and is preferably 200 to 300° C. (in the case of an embodiment of a GST system). Also, the vacuum atmosphere is preferably 10⁻³ to 10⁻⁶ Torr.

Also, the applied voltage and applied time of the pulse voltage are simultaneously controlled and 4 to 6V is preferably supplied for a period of 50 to 500 ns (in the case of an embodiment of a GST system).

Preferably, the method further comprises cooling the substrate in order to generate the single crystal nano-structures on the substrate after the vaporization of the target member.

In order to accomplish the objects, there is provided a device for manufacturing nano-structures according to the present invention comprises: a main chamber connected to a vacuum apparatus to form a space with a vacuum atmosphere; a base having a heating means mounted to a bottom surface inside the main chamber and disposed with a target member; a holder mounted to be spaced from the base and capable of fixing a substrate to have a constant distance from the target member; a displacement means controlling a distance between the target member and the substrate by vertically displacing the holder; a cooling means mounted to the holder to cool the substrate; and a pulse voltage applying means for applying a pulse voltage to the target member.

The vacuum apparatus may comprise any one of a rotary pump and a turbo molecular pump and the heating means is preferably an electronic heater.

And, a thermocouple is inserted and mounted between the holder and the base in order to accurately control a temperature.

The cooling means may comprise a cooling tube passing through nitrogen gas and a heat exchanger exchanging heat with the cooling tube at the outside of the main chamber.

Also, the displacement means may be formed of a PZT scanner for an atomic force microscope or a Z-motion unit.

The pulse voltage applying means has a pulse generator, a controller controlling the applied time of the pulse voltage and an electrode contacting the target member to connect to the controller, the electrode having a shape of a cone or a polygonal cone. Among others, tip morphology for the AFM is most preferable and its vertex preferably contacts the target member.

At this time, one end of the electrode contacts the target member, the other end thereof is fixed to the electrode fixing part mounted inside the main chamber, or the one end thereof contacts the target member and the other end thereof is fixedly mounted to the substrate. In this case, when the tip for the AFM is used, the tip contacts a thin film of the target member, and a cantilever portion becomes the substrate.

Another invention is a storage medium using GST nano-structures manufactured by means of the single crystal nano-structures manufacturing method as described above.

As described above, the present invention relates to a method for manufacturing nano-structures capable of the synthesis a morphology control and a device for manufacturing the nano-structures, according to variables such as a temperature of a substrate in a vacuum system, an applied voltage applied to the target member, a pulse width of the applied voltage, etc. In the case of a chalcogenide-based GST nano-structures growing method, a melting point of a GST thin film is 632° C., while a temperature of a target member (GST) is about 200 to 300° C., and an application of about 5V for a period of 300 ns is needed.

In other words, the present invention has an advantage that manufacturing cost is very low due to a low temperature and short process time.

Also, each of the nano-structures of the present invention can be used as a unit of a storage medium so that a high density storage medium can be manufactured and various devices can be miniaturized by using particular electrical and physical characteristics that are exhibited in a nano-sized semiconductor or metal.

In other words, the present invention is expected to be used as a semiconductor technology by applying the existing Si base technology as it is because this allows the growth of single crystals on substrates (for example, Pt/Ti/SiO₂/Si substrate) whose directivities conform to each other.

If small sized single crystal nano-structures are grown at desired positions using the chalcogenide-based nano-structures capable of being manufactured according to the present invention, a cell can be immediately manufactured without any secondary works and can be used as the phase-change random access memory.

Also, various nano-structures in desired morphologies can be manufactured without a limitation of materials according to various variables and various embodiments of the present invention.

### BRIEF DESCRIPTION OF THE DRAWINGS

These and other objects, features, and advantages of preferred embodiments of the present invention will be more fully described in the following detailed description, taken in conjunction with the accompanying drawings. In the drawings:

FIG. 1 is a schematic view of a single crystal nano-structures manufacturing device according to embodiment 1 of the present invention.

FIG. 2 is a schematic view of a single crystal nano-structures manufacturing device according to embodiment 2 of the present invention.

FIG. 3 is an SEM image of ST nano-structures experiencing various morphology controls in the range where a temperature of a target member is 200° C. to 300° C.

FIGS. 4A and 4B are SEM images of the GST nano-structures grown on an AFM cantilever with an application of 5V for a period of 300 ns in the case where the temperature of the target member is 300° C.

FIG. 5 is an optical photograph before and after the nano-structures are grown at each temperature.

FIG. 6 is an SEM image of the GST nano-structures formed on several patterned substrates.

FIG. 7 is photograph and graph of structural and electrical characteristic evaluation results of the GST nano-structures experiencing a morphology control.

FIG. 8 is set/reset repeated experimental results of the GST single crystal nanowire with a diameter of 100 nm.

### DETAILED DESCRIPTION OF THE INVENTION

Hereinafter, preferred embodiments of the present invention will be described with reference to the accompanying drawings. In referring reference numerals to elements of each drawing, like reference numerals refer to like elements throughout the drawings. Detailed descriptions of known functions and constitutions are omitted so as not to obscure the description of the present invention with unnecessary detail.

Through a method for manufacturing nano-structures proposed in the present invention, the nano-structures capable of the synthesis a morphology control can be manufactured according to variables such as a temperature of a substrate in a vacuum system, an applied voltage applied to the target member, a pulse width of the applied voltage, a kind of the target member etc.

First, a target member performing a function of supplying precursors and a substrate having the nano-structures formed thereon are put in place.

At this time, the space where the target member and the substrate are disposed is a vacuum atmosphere with a vacuum state of about 10⁻³ to 10⁻⁶ Torr.

And, the target member and the substrate are disposed to have a distance of 10 to 90 μm therebetween.

The distance can be precisely controlled by using a Z-motion unit or a PZT scanner.

Also, the target member is heated so as to be vaporized, the heating temperature being below a melting point of a supplied thin film and is preferably 200 to 300® C. (in the case of an embodiment of a GST).

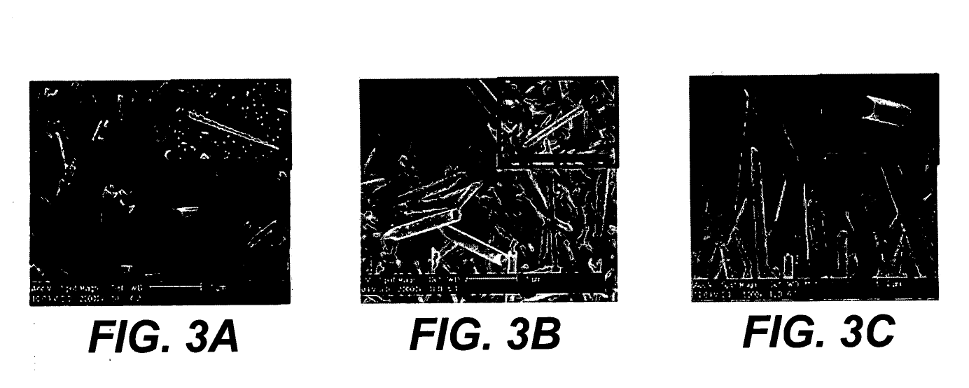

The temperature control can be performed by an electronic heater. In the case of a chalcogenide-based GST, the nano-structures morphology control can be performed according to the temperature. In other words, the nano-structures morphology control can be performed. When the temperature of the target member is 200° C., it is grown as a nanotube with inverted pyramid morphology. When the temperature of the substrate is 300° C., it is grown as a nanowire with hexagonal cylinder morphology (see FIG. 3).

A pulse voltage of 10 to 900 ns (nano-seconds) of 4 to 6V is applied to the heated target member as above. This is to vaporize a thin film according to a generation of thermal energy between electrodes bonded to the target member.

If the pulse voltage is applied as above, the target member is vaporized to move into the substrate so that it is regrown in the desired nano-structures morphology.

At this time, it is preferable to accelerate the crystallization by lowering the temperature of the substrate in order to generate the nano-structures. To this end, it is preferable to mount a cooling means capable of cooling the substrate.

A storage medium using the GST nano-structures can be manufactured using the single crystal nano-structures manufacturing method as above.

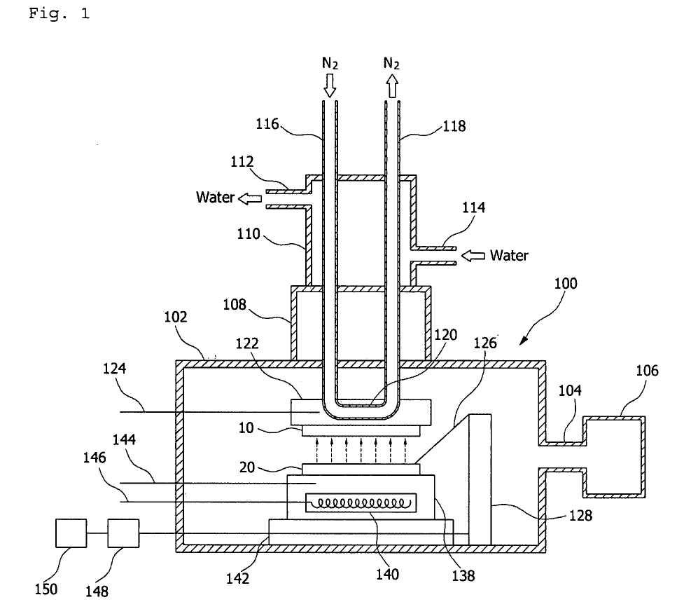

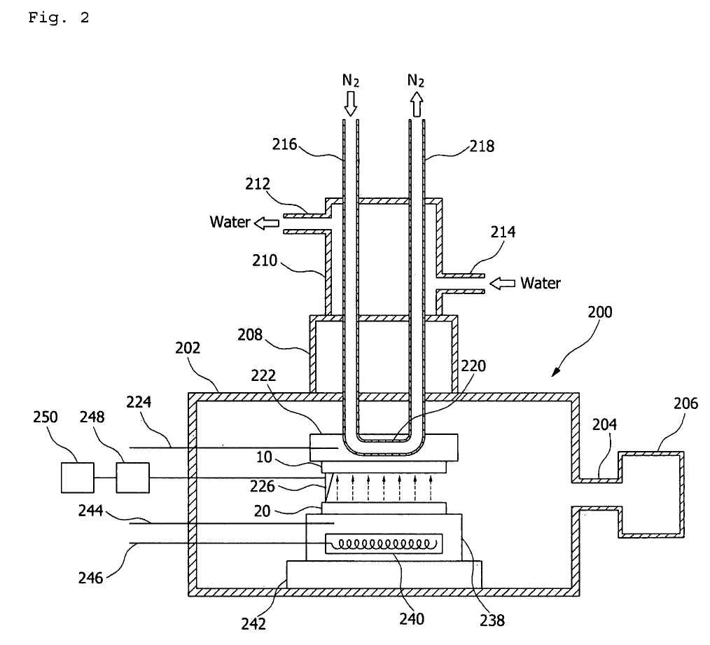

In order to form the nano-structures as above, the device for manufacturing the nano-structures as shown in FIGS. 1 and 2 is proposed in the present invention.

First, the nano-structures manufacturing device 100 according embodiment 1 comprises a main chamber 102 connected to a vacuum apparatus 106 to form a space with a vacuum atmosphere; a base 138 having a heating means mounted to a bottom surface inside the main chamber 102 and disposed with a target member 20; a holder 122 mounted to be spaced from the base 138 and capable of fixing a substrate 10 (the case of using a conductive AFM tip) to have a constant distance from the target member 20; a displacement means controlling a distance between the target member 20 and the substrate 10 by vertically displacing the holder 122; a cooling means mounted to the holder 122 to cool the substrate 10; and a pulse voltage applying means for applying a pulse voltage to the target member 20. If needed, the target member 20 and the substrate 10 may be positioned vice versa.

The vacuum apparatus 106 may comprise a rotary pump and/or a turbo molecular pump which is connected to the main chamber 102 by means of a pipe (104).

The lower portion of the base 138 may be further mounted with an insulation member 142 in order to prevent an influence of the temperature on other portions.

And, the heating means 140 included in the base 138 uses an electronic heater suitable for controlling temperature. Electricity is supplied to the electronic heater by means of a power supply line 146.

Also, a thermocouple 144 is buried in the upper side of the base 138, making it possible to determine the temperature of the target member 20 mounted to the base 138.

In the space above the base 138 is mounted a holder 122.

The holder 122 can be vertically displaced by means of the displacement means. In embodiment 1 of the present invention, a piezo-motion unit 108 is used as the displacement means. In this case, an AFM for high temperature is used. The vertical displacement means of the holder 122 is also operated by means of the Z-motion unit.

The Z-motion unit 108 displaces the holder 122 by moving the cooling tube 120 up and down, which is integrally formed with the holder 122. Of course, the holder 122 can be displaced by other means.

And, the holder 122 is inserted and mounted with the thermocouple 124 in order to accurately control the temperature.

The temperature of the substrate 10 can be determined through the temperature information of the thermocouple 124. Therefore, the temperature or the supply amount of nitrogen gas through the cooling tube 120 can be controlled.

The cooling means may comprise the cooling tube 120 passing through the nitrogen gas, and a heat exchanger 110 exchanging heat with the cooling tube 120 in the outside of the main chamber 102.

The cooling tube 120 comprises a gas inlet 116 receiving the nitrogen gas and a gas outlet 118 discharging the nitrogen gas.

The heat exchanger 110 uses a water cooling system since it is cost-effective. As shown in FIG. 1, cooling water flows in a cooling water inlet 114 and is heat-exchanged with the cooling tube 120. Thereafter, the cooling water is discharged to a cooling water outlet 112.

Also, the pulse voltage applying means comprises a pulse generator 150, a controller 148 controlling the application time of the pulse voltage generated by the pulse generator 150, and an electrode 126 contacting the target member 20 to connect to the controller.

The electrode 126 has a shape of a cone or a polygonal cone and its vertex contacts the substrate 10.

At this time, one end of the electrode 126 contacts the target member 20, and the other end thereof is fixed to the electrode fixing part 128 mounted inside the main chamber 102 or is connected to a AFM circuit.

Accordingly, if the target member 20 is vaporized by means of the electrode 126, the target member 20 becomes thinner by the vaporized amount so that the electrode 126 and the target member 20 are electrically isolated from each other.

The target member 20 performing a function of supplying the precursor is a morphology suitable for depositing the thin film of composition to a thickness of 50 to 200 nm, which allows deposition and growth of an electrode such as TiN, Pt, etc., on a Si wafer.

Also, the substrate 10 performing a function of receiving the precursor is a conductive AFM cantilever and should be processed to maintain a crystallographic bonding relation with the nano-structures to be grown.

The nano-structures can be arranged in any direction by using an external electric field together with the crystal orientation of the thin film where the nano-structures are grown.

Next, the nano-structures manufacturing device according to embodiment 2 will be described with reference to FIG. 2. The nano-structures manufacturing device 200 according embodiment 2 is similar in coustrucion and function as the nano-structures manufacturing device 100 according embodiment 1 illustrated in FIG. 1 except the substrate, and like elements are referred to using like reference numerals wherein, for example, 100 and 102 correspond to 200 and 202, respectively. The description of the same portion as embodiment 1 will be omitted in embodiment 2.

In other words, in the nano-structures manufacturing device 200 according to embodiment 2, the substrate 10 is a substrate that is used for manufacturing the thin film or the nano-structures.

An electrode 226 of the nano-structures manufacturing device 200 according to embodiment 2 is formed to be integrated with the substrate 20 in a tip form. The substrate 10 is moved by means of the Z-motion unit 208 to control the distance between the substrate 10 and the target member 20.

At this time, the target member 20 is vaporized by means of the electrode 226, the target member 20 becomes thinner by the vaporized amount so that the electrode 226 and the target member 20 are electrically isolated from each other.

FIG. 3 is an SEM image of GST nano-structures experiencing various morphology controls by controlling the temperature of the target member in the range of 200° C. to 300° C., and by using the AFM cantilever as the substrate when using embodiment 1. (a) is a nanotube with an inverted pyramid morphology manufactured when the temperature of the target member is 200° C. or less. (b) is a nanotube morphology manufactured when the temperature of the target member is 200° C., an end portion of the nanotube is an inverted pyramid morphology. However, the nanotube exhibits straight upward growing tube morphology when exceeding predetermined length. (c) is a nanowire manufactured when the temperature of the target member is 300° C., its morphology is a long hexagonal rod.

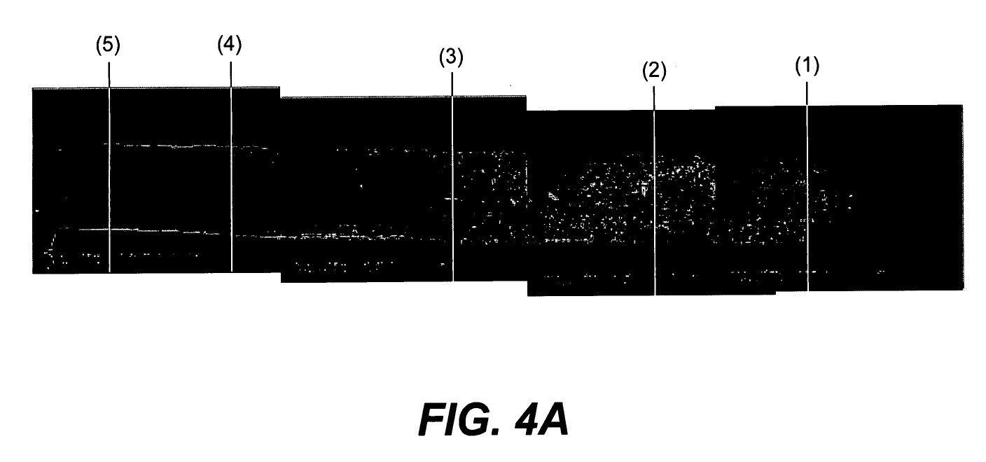

FIG. 4 is the entire SEM image of the GST nano-structures grown on the cantilever with an application of 5V for a period of 300 ns in the case where the temperature of the target member is 300° C., by using embodiment 1. Differences in morphology due to temperature variation is confirmed in order as going away from the portion near the tip. It can be appreciated that the nearest portion of the tip shows the nanowire morphology and the middle portion thereof shows the nanotube morphology in the form of an inverted pyramid.

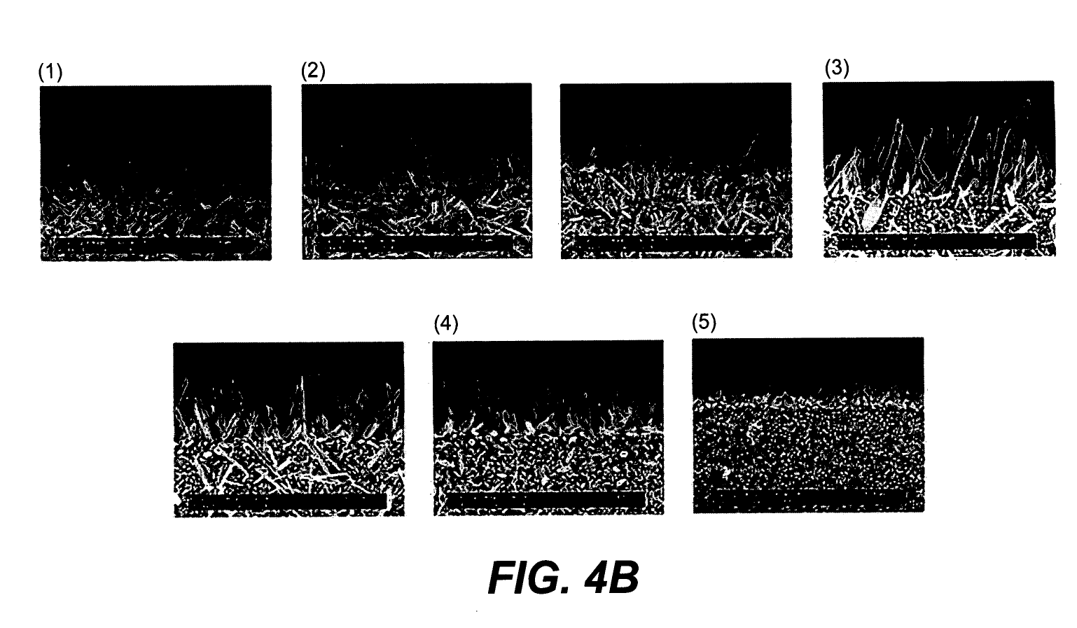

FIG. 5 is an optical photograph before and after the nano-structures are grown at each temperature, by using embodiment 1. The case of (a-1) is a photograph of the thin film cantilever substrate and the target member in a state where the temperature of the target member is heated to 200° C. and the case of (a-2) is an optical photograph immediately after 5V is applied to a sample for a period of 300 ns where the temperature of the target member is heated to 200° C.

The case of (b-1) is a photograph of the thin film cantilever substrate and the target member in a state where the temperature of the target member is heated to 300° C. and the case of (b-2) is an optical photograph immediately after 5V is applied to a sample for a period of 300 ns where the sample is heated to 300° C.

The change before and after the external pulse voltage is applied can be confirmed through FIG. 5. That is, it can be confirmed that the surface of the target member thin film is considerably damaged after the pulse voltage is applied.

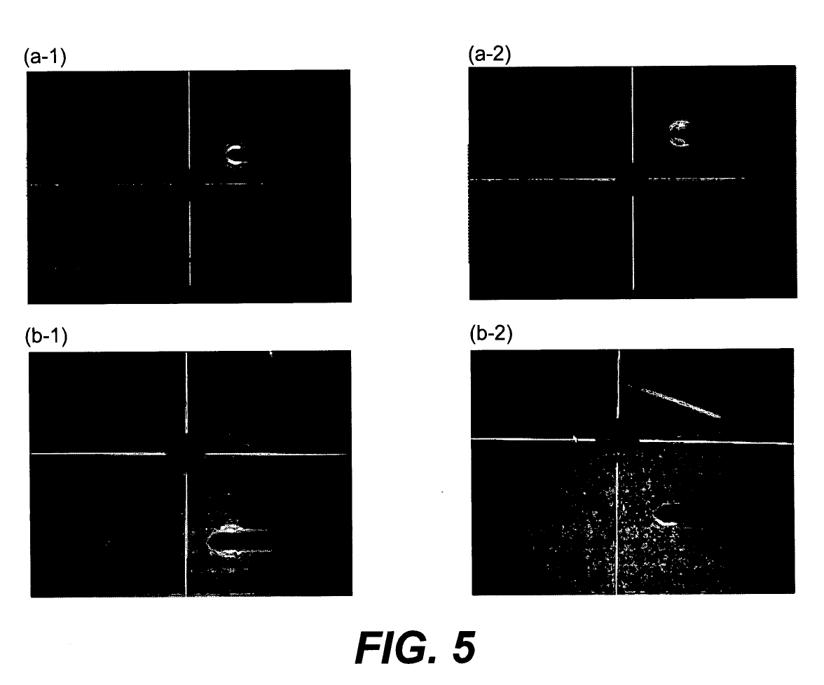

FIG. 6 is an SEM image of the GST nano-structures formed on several substrates patterned and machined by using embodiment 2.

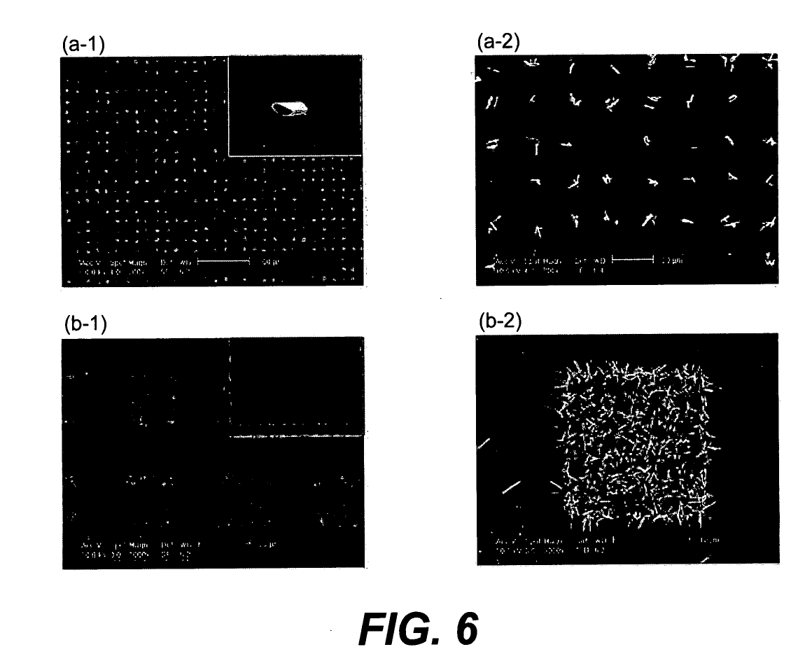

FIG. 7 is structural and electrical characteristic evaluation results of the GST nano-structures experiencing a morphology control, manufactured by means of the nano-structures manufacturing method of the present invention.

(a) is an SEM image of the nanotube manufactured when the temperature of the target member is 200° C. in embodiment 1. (b) is an SEM image of the nanotube manufactured when the temperature of the target member is 300° C. in embodiment 1. (c) is the analysis results of compositions of the nano-structures, wherein the compositions thereof conform to the compositions of the target member. (d) is I-V characteristic results (a red line) of the GST single crystal nano-structures with a diameter of 100 nm and the I-V characteristic after the pulse voltage is applied is shown by a black line. (e) is I-V characteristic results in an initial crystal state and a final amorphous state after the pulse voltage is applied.

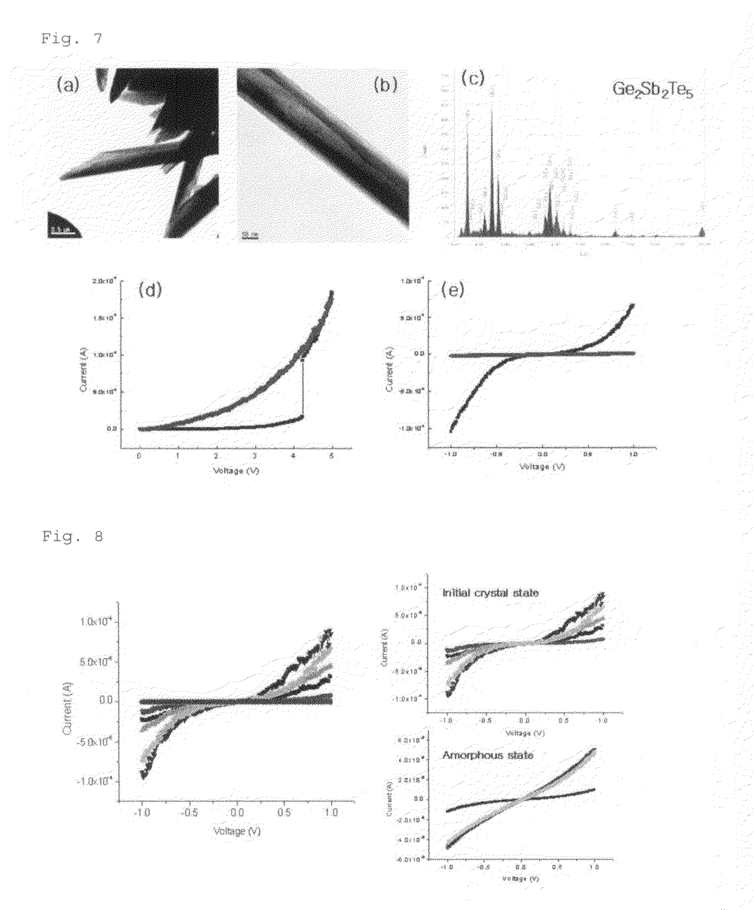

FIG. 8 is set/reset repeated experimental results of the GST single crystal nanowire with a diameter of 100 nm. A reversible phase-change from the initial crystal state to the amorphous state and back to the crystal state is confirmed through the difference of electric resistance.

### TEST EXAMPLE 1

In the process of manufacturing the GST nanotube when the temperature of the target member is 200° C. in embodiment 1, a 2 cm×2 cm Si wafer with a thickness of 200 μm is prepared. After TiN (100 nm)/Ti (20 nm) is deposited on the wafer, the GST target member thin film with the composition of 2:2:5 confirmed through ICP-AES Induced Coupled Plasma—Atomic Emission Spectroscopy with a thickness of 100 nm is then deposited thereon.

At this time, the GST is deposited so that about 1 to 2 mm of the lower electrode for ground is exposed. The deposited thin film as above is cut to a size of about 5 mm×5 mm. Thereafter, it is mounted on the base 138 of FIG. 1.

The target member (sample) prepared as above is adhered to the upper portion of the heater using a silver paste for high temperature and the lower electrode is then connected to the heater, thereby forming the ground. The tip attached to the cantilever substrate for the AFM coated with Pt contacts the GST thin film and the temperature of the heater is then set to 200° C.

The temperature of the heater is increased so that the setting temperature is reached after about 5 minutes have elapsed. The temperature is uniformly formed by maintaining this state for another 5 minutes. Thereafter, 5V is applied to an SEM tip for a period of 300 ns.

At this time, the GST thin film is vaporized and at the same time, the tip and the target member contacting each other are separated. This can be confirmed on an AFM controller. The distance between the cantilever substrate and the tip, detected by means of a photo detector, is increased by the vaporization simultaneously with the application of pulse from the pulse generator. At this time, the grown nanotube morphology can be confirmed through a microscope.

It can be confirmed that the tube has grown lengthwise through the edge and inside of the cantilever substrate. At this time, the morphology is a hexagonal morphology like a honeycomb structure (see FIG. 3(b)).

### TEST EXAMPLE 2

In the process of manufacturing the GST nanowire when the temperature of the target member is 300° C. in embodiment 1, the sample is prepared in the same method as the preparation of the GST sample for manufacturing the GST nanotube. Thereafter, it is mounted on the base 138 of FIG. 1. The sample prepared as above is adhered to the upper portion of the heater using the silver paste for high temperature and the lower electrode is then connected to the heater, thereby forming the ground.

The tip of the cantilever substrate coated with Pt contacts the GST thin film and the temperature of the heater is then set to 300° C. The temperature of the heater is increased so that the setting temperature is reached after about 7 minutes have elapsed. The temperature is uniformly formed by maintaining this state for another 5 minutes.

Thereafter, 5V is applied to the tip for a period of 300 ns. At this time, the GST thin film is vaporized and at the same time, the tip and the target member contacting each other are separated. This can be confirmed on an AFM controller. The numerical value of the distance between the tip and the target member is changed to 100 μm simultaneously with the application of pulse from the pulse generator. At this time, the nanowire morphology can be confirmed through a microscope. It can be confirmed that the wire has grown lengthwise through the edge of the tip. At this time, the morphology is a long hexagonal rod (see FIG. 3(c)).

### TEST EXAMPLE 3

In the case where the nano-structures are grown by the method as above at about 250° C., that is an intermediate temperature between 200° C. and 300° C., they are grown in the intermediate morphology of the nanotube and the nanowire. That is, they are grown in a morphology similar to the wire having more filled inside than that of the nanotube. Thus the inside of these nano-structures has less filled morphology than that of the nanowire.

Although the present invention has been described in detail reference to its presently preferred embodiment, it will be understood by those skilled in the art that various modifications and equivalents can be made without departing from the spirit and scope of the present invention, as set forth in the appended claims.

What is claimed is:

1. A method for manufacturing single crystal nano-structures capable of controlling morphology comprising the steps of:
disposing a target member supplying precursors inside a space with a vacuum atmosphere;
disposing a substrate to be formed with the nano-structures above or below the target member;
controlling a gap between the target member and the substrate;
heating the target member at a constant temperature according to the desired morphology of the nano-structures;
vaporizing the target member by applying a pulse voltage to the target member; and
growing the vaporized precursors on the substrate in the form of single crystal nano-structures.

2. The method as claimed in claim 1, wherein the target member is formed of materials with an anisotropic 2D layered structure such as GST, graphite, MoS₂, BN, WS₂, V₂O₅ etc., and materials with semiconductor characteristics such as Si, Ge, GaP, GaAs, etc.

3. The method as claimed in claim 1, wherein the target member is a thin film.

4. The method as claimed in claim 1, wherein the heating temperature is below the melting point of the target member.

5. The method as claimed in claim 1, wherein the heating temperature of the target member is 200 to 300° C. in the case of GST.

6. The method as claimed in claim 1, wherein the vacuum atmosphere is 10⁻³ to 10⁻⁶ Torr.

7. The method as claimed in claim 1, wherein the applied voltage and applied time of the pulse voltage applied to the target member are simultaneously controlled to vaporize the target member.

8. The method as claimed in claim 1, wherein a pulse voltage of 4 to 6V is supplied for a period of 50 to 500 ns in the case of the GST target member.

9. The method as claimed in claim 1, further comprising cooling the substrate in order to generate the single crystal on the substrate after the vaporization of the target member.

10. A device for manufacturing nano-structures comprising:
a main chamber connected to a vacuum apparatus to form a space with a vacuum atmosphere;
a base having a heating means mounted to a bottom surface inside the main chamber and disposed with a target member;
a holder mounted to be spaced from the base and capable of fixing a substrate to have a constant distance from the target member;
a displacement means controlling a gap between the target member and the substrate by vertically displacing the holder;
a cooling means mounted to the holder to cool the substrate; and
a pulse voltage applying means for applying a pulse voltage to the target member.

11. The device as claimed in claim 10, wherein the vacuum apparatus comprises any one of a rotary pump and a turbo molecular pump

12. The device as claimed in claim 10, wherein the heating means is an electronic heater.

13. The device as claimed in claim 10, wherein a thermocouple is inserted and mounted between the holder and the base.

14. The device as claimed in claim 10, wherein the cooling means comprises a cooling tube passing through nitrogen gas and a heat exchanger exchanging heat with the cooling tube at the outside of the main chamber.

15. The device as claimed in claim 10, wherein the displacement means is a PZT (Piezo-motion) scanner or a Z-motion unit.

16. The device as claimed in claim 10, wherein the pulse voltage applying means has a pulse generator, a controller controlling the applied time of the pulse voltage, and an electrode contacting the target member to connect to the controller.

17. The device as claimed in claim 16, wherein the electrode has a shape of a cone or a polygonal cone and its vertex contacts the target member.

18. The device as claimed in claim 16, wherein one end of the electrode contacts the target member and the other end thereof is fixed to the electrode fixing part mounted inside the main chamber.

19. The device as claimed in claim 16, wherein the one end of the electrode contacts the target member and the other end thereof is fixedly mounted to the substrate.

20. A storage medium manufactured by means of the method for manufacturing single crystal nano-structures as claimed in claim 1.
